(19) United States
(12) Patent Application Publication
(10) Pub. No.: US 2022/0187350 A1
(43) Pub. Date: Jun. 16, 2022

(54) TEST METHOD FOR HIGH-SPEED SIGNAL FREQUENCY MEASUREMENT AND SIGNAL INTEGRITY

(71) Applicant: NANJING MACROTEST SEMICONDUCTOR TECHNOLOGY CO., LTD., Nanjing (CN)

(72) Inventor: CHUNWEI XIAO, Nanjing (CN)

(21) Appl. No.: 17/653,471

(22) Filed: Mar. 4, 2022

Related U.S. Application Data
(63) Continuation of application No. PCT/CN2020/129978, filed on Nov. 19, 2020.

(30) Foreign Application Priority Data
Oct. 19, 2020 (CN) 202011115382.4

(51) Int. Cl. G01R 23/02; G01R 31/317

(52) U.S. Cl. CPC G01R 23/02; G01R 31/31708

(57) ABSTRACT

The invention discloses a test method for high-speed signal frequency measurement and signal integrity. Through the combination of integrated circuit digital-analog test system and programmable digital system, the trigger signal of the test system is synchronized with the digital signal of the peripheral test circuit to generate 100 M square wave and data to verify whether the chip can work normally. When the enabling signals of the integrated circuit digital-analog test system are detected by the peripheral test circuit, the corresponding square wave signal of 100 M or the preset data signal are given to the tested digital chip. The two enabling signals have the same priority, and then sample the output of the tested digital chip, wherein, the collected output waveform needs to be logically calculated and divided into a 10 M square wave, and the frequency measurement is carried out, then the processed results are returned to the test system. The test system accurately selects the chip with correct function according to the data, and eliminates the chip with abnormal work.

### CROSS-REFERENCE TO RELATED APPLICATIONS

This application is a continuation of International Patent Application Number PCT/CN2020/129978, filed on Oct. 27th, 2020, which claims the benefit and priority of Chinese Patent Application Number 202011115382.4, filed on Oct. 19th, 2020 with China National Intellectual Property Administration, the disclosures of which are incorporated herein by reference in their entireties.

### TECHNICAL FIELD

The invention relates to the technical field of integrated circuit testing, in particular to a test method for high-speed signal frequency and signal integrity.

### BACKGROUND TECHNOLOGY

With the rapid development of integrated circuit technology, more and more high-speed digital chips are applied to various fields. In the process of data transmission and storage of digital chips, if the transmitted and stored waveform data is distorted or confused, it will have a great impact on the function of the entire digital system, and even fail to work properly and bring security risks. Therefore, if the digital chips with incongruent functional description are identified and eliminated before application, it can effectively avoid the economic and security risks brought by the later stage of electronic system construction.

### The Content of the Invention

The purpose of the invention is to provide a test method for high-speed signal frequency measurement and signal integrity, which can accurately identify and eliminate unqualified digital chips.

To achieve the above purpose, the invention provides a test method for high-speed signal frequency measurement and signal integrity, including the following steps:

Receive the enabling signal sent by the integrated circuit test system, and carry out signal frequency measurement or integrity test according to the type of the enabling signal;

If the signal frequency measurement is carried out, the generated square wave is transmitted to the tested digital chip, and the frequency measurement is carried out after frequency-dividing the output signal of the tested digital chip;

If the signal integrity test is carried out, the generated data signal is transmitted to the tested digital chip, at the same time, the output data of the tested digital chip is sampled and stored for comparison;

Whether the digital chip under test is qualified is judged according to the comparison result of the received frequency measurement result and the signal integrity data.

Wherein, if the signal frequency is measured, the generated square wave is transmitted to the tested digital chip, and the frequency measurement of the output signal of the tested digital chip is carried out after frequency division, including:

The square wave with a frequency of 100 M generated by the test load plate is transmitted to the tested digital chip according to the received waveform enabling signal. At the same time, the output waveform of the tested digital chip is collected and the output waveform is logically calculated and divided into a 10 M square wave.

Wherein, if the signal frequency is measured, the generated square wave is transmitted to the tested digital chip, and the frequency measurement is carried out after dividing the output signal of the tested digital chip, including:

Adjust the measurement parameters of the time measurement board on the integrated circuit test system, input the frequency-divided output waveform into the adjusted time measurement board for measurement, and output frequency measurement values and comparison results.

Wherein, if the signal integrity test is carried out, the generated data signal is transmitted to the tested digital chip, at the same time, the output data of the tested digital chip is sampled and stored for comparison, including:

After receiving the signal of the data emitted by the integrated circuit test system, the peripheral circuit is used to send the preset data of the internal register to the tested digital chip, and then the output of the measured digital chip is sampled at a sampling frequency of 200 M, and whether sampling results and preset data are the same is compared in the internal register.

Wherein, whether the digital chip under test is qualified is judged according to the comparison result of the received frequency measurement result and the signal integrity data, including:

Judge whether the received frequency measurement value is within the allowable fluctuation range during the 100M transmission of the test digital chip:

If the frequency measurement value is greater than or equal to the lower limit of the frequency specification value, and less than or equal to the upper limit of the frequency specification value, the tested digital chip is a good product;

If the measured frequency value is smaller than the lower limit value of the frequency specification value, or greater than the upper limit value of the frequency specification value, the tested digital chip is a defective product.

The invention discloses a test method for high-speed signal frequency measurement and signal integrity. Through the combination of integrated circuit digital-analog test system and programmable digital system, the trigger signal of the test system is synchronized with the digital signal of the peripheral test circuit to generate 100 M square wave and data to verify whether the chip can work normally. When the enabling signals of the integrated circuit digital-analog test system are detected by the peripheral test circuit, the corresponding square wave signal of 100 M or the preset data signal are given to the tested digital chip. The two enabling signals have the same priority, and then sample the output of the digital chip under test, wherein, the collected output waveform needs to be logically calculated and divided into a 10 M square wave, and the frequency measurement is carried out, and the processed results are returned to the test system. The test system accurately selects the chip with correct function according to the data, and eliminates the chip with abnormal work.

### BRIEF DESCRIPTION OF THE FIGURES

In order to more clearly illustrate the technical scheme in the embodiment or existing technology of the invention, the attached figures used in the embodiment or existing technology description will be briefly introduced below. Obviously, the figures in the following description are only some embodiments of the present invention, and for ordinary technicians in this field, other figures can be obtained according to these figures without paying creative labor.

FIG. 1 is a schematic diagram of steps of a test method for a high-speed signal frequency and signal integrity provided by the present invention.

FIG. 2 is a schematic flow chart of a test method for a high-speed signal frequency measurement and signal integrity provided by the present invention.

FIG. 3 is a schematic diagram of the frequency division specification of frequency measurement provided by the present invention.

### SPECIFIC IMPLEMENTATION METHODS

Embodiments of the present invention are described in detail below. The example of the embodiment is shown in the attached figures, wherein the same or similar labels from beginning to end represent the same or similar components or components with the same or similar functions. The embodiments described below with reference to the attached figures are exemplary, which are intended to explain the present invention and should not be understood as restrictions on the invention.

In the description of the invention, “plurality” means two or more, unless there are clear and specific limits.

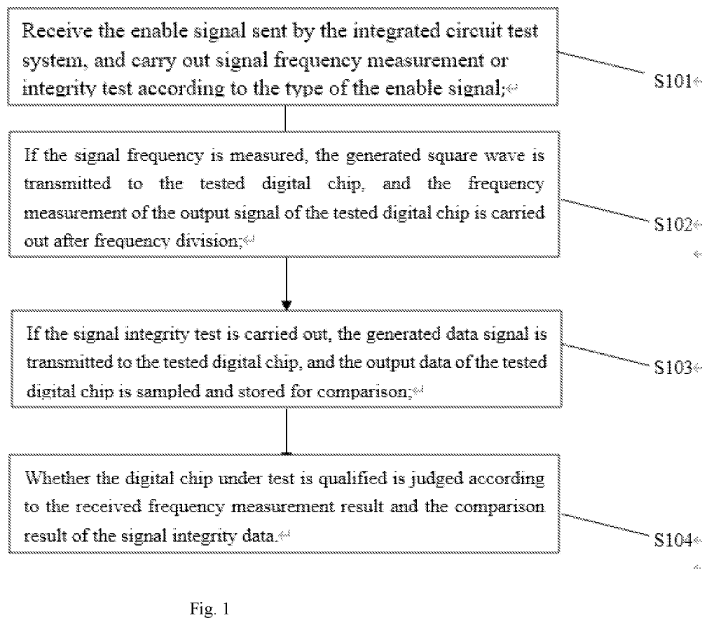

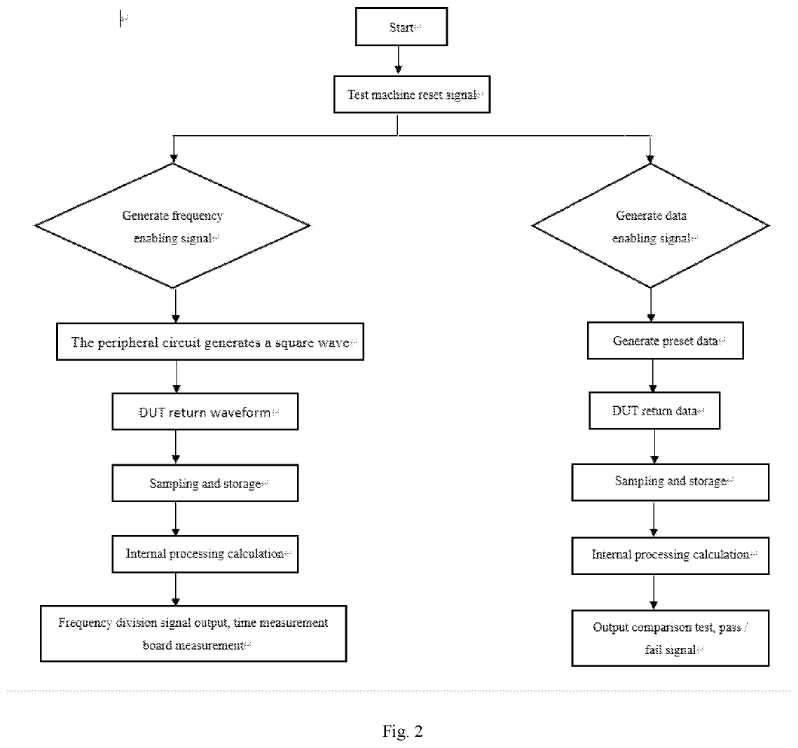

Please refer to FIG. 1 and FIG. 2, the invention provides a test method for high-speed signal frequency measurement and signal integrity, including the following steps:

S101: Receive the enabling signal sent by the integrated circuit test system, and carry out signal frequency measurement or integrity test according to the type of the enabling signal;

Specifically, the device for detecting digital chips includes a test platform, a test load board, and an interface of the measured device. The test platform is connected to the test load plate, the test load plate is connected to the interface of the tested device, the interface of the tested device is connected to the digital chip, and the test program is edited on the test platform; According to the test specification of the digital chip, make preparations for the chip before testing, including: edit the test program correctly on the test platform, connect the test platform, test load board, test device interface, and digital chip.

Specifically, the following sub steps are included:

Design and manufacture the test load board and the test device (DUT) interface according to the test specification of the digital chip;

Edit the test program on the test platform according to the test specification of the digital chip. For example, edit and debug the test program on the MS7000 according to the test specification;

Connect the test load board and the DUT interface.

When the test machine generates a reset signal, the test system will generate a waveform or data enabling signal. After detecting that the integrated circuit test system sends an enabling signal to the test peripheral circuit, the test peripheral circuit determines the type of enabling signal based on the voltage changes of the different ports to determine the signal frequency measurement or integrity test. The peripheral circuit generates a 100M square wave signal or a preset data signal at the same output port according to the different enabling signals of the test system, and the two enabling signals have the same priority.

S102: if the signal frequency is measured, the generated square wave is transmitted to the tested digital chip, and the frequency measurement of the output signal of the tested digital chip is carried out after frequency division, including:

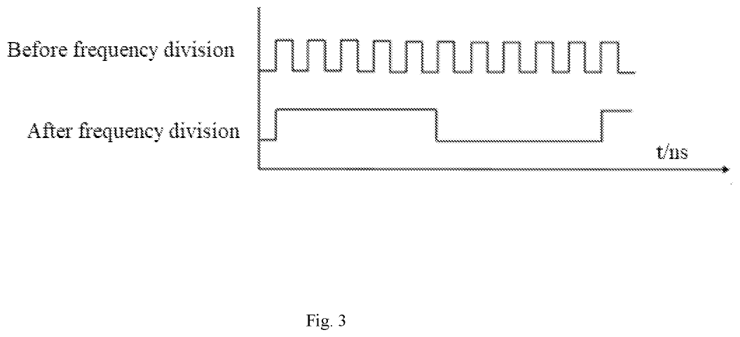

Specifically, the test platform sends the waveform enabling signal to the test load board. After the circuit on the test load board receives waveform enabling signal, the peripheral circuit generates a square wave with a frequency of 100 M and a duty cycle of 50%. The square wave is sent to the digital chip and the output waveform of the digital chip output end is collected. The circuit on the test load board divides the sampled output waveform decade frequency, and the specific implementation method is to count every five rising edge transitions of the output waveform to change the polarity of the output state once. The process is a continuous process to generate continuous signals, and the effect diagram is shown in FIG. 3.

The test program sets the relevant parameters of the time measurement board of the test platform to accurately measure the frequency of 10 M square waves. The test load card sends the divided waveform signal to the time measurement board of the test platform, and the time measurement board of the test platform measures the actual frequency value. If the actual frequency value is greatly different from the theoretical 10M value, then the test platform classifies the chip as a defective product, otherwise it is a good product. During the signal frequency measurement, in order to generate a stable waveform signal and send it to the input end of the digital chip, the peripheral circuit uses a PLL to achieve a stable and high-frequency signal and output it.

S103: If the signal integrity test is carried out, the generated data signal is transmitted to the tested digital chip, and the output data of the tested digital chip is sampled and stored for comparison.

Specifically, the test platform sends the enabling signal of the generated data to the test load board. After the circuit on the test load board receives the enabling signal of the generated data, the peripheral circuit is used to send the preset data of the internal register to the tested digital chip. That is to say, a piece of data starting with a specific sequence is generated by the peripheral circuit, and a bit of data is sent to the digital chip every 10 ns interval and sent to the input end of the digital chip. The peripheral circuit collects the output data of the digital chip while sending data. This piece of data is stored in the storage unit of the peripheral circuit or in the internal register. The peripheral circuit collects the data at the output end of the digital chip while sending the data and stores the collected output data in the storage unit of the peripheral circuit in sequence.

Detect the data in the storage unit. When a specific start sequence is detected, whether the data after comparison are consistent with the expected value or not. If all are consistent, the test load board sends a Pass signal to the test platform, and vice versa, it sends a Fail signal.

S104: Whether the digital chip under test is qualified is judged according to the comparison result of the received frequency measurement result and the signal integrity data.

Specifically, after obtaining the comparison result of the frequency measurement value of the digital chip and the signal integrity, it is judged whether the received frequency measurement value is within the allowable fluctuation range during the 100M transmission of the test digital chip, and the digital chip with good consistency is selected. Specifically it includes whether the received frequency measurement value is within the allowable fluctuation range during the 100M transmission of the test digital chip: if the frequency measurement value is greater than or equal to the lower limit of the frequency specification value, and less than or equal to the upper limit of the frequency specification value, the tested digital chip is a good product; If the measured frequency value is smaller than the lower limit value of the frequency specification value, or greater than the upper limit value of the frequency specification value, the tested digital chip is a defective product. At the same time, whether the tested digital chip is a good product is judged according to the comparison results of frequency measurement and signal integrity data.

The above two test items together with routine digital chip test items, such as open-short circuit (OS) test items, operating current and quiescent current test items (IDD), input and output threshold test items (THRESHOLD), state-on voltage test value (UVLO), the default output state (DEFAULT), the delay time of the input and output channels (TPLH, TPHL) and other test items constitute a complete routine test process for digital chips, which can screen most chips that do not meet the functional description.

The invention discloses a test method for high-speed signal frequency measurement and signal integrity. Through the combination of integrated circuit digital-analog test system and programmable digital system, the trigger signal of the test system is synchronized with the digital signal of the peripheral test circuit to generate 100 M square wave and data to verify whether the chip can work normally. When the enabling signals of the integrated circuit digital-analog test system are detected by the peripheral test circuit, the corresponding square wave signal of 100 M or the preset data signal are given to the tested digital chip. The two enabling signals have the same priority, and then sample the output of the tested digital chip, wherein, the collected output waveform needs to be logically calculated and divided into a 10 M square wave, and the frequency measurement is carried out, then the processed results are returned to the test system. The test system accurately selects the chip with correct function according to the data, and eliminates the chip with abnormal work.

What is disclosed above is only a better embodiment of the invention, and of course it cannot be used to limit the scope of rights of the present invention. Ordinary technical personnel in this field can understand and realize the whole or part of the process of the above embodiment, and the equivalent changes made in accordance with the present invention are still within the scope of the invention.

I claim:

1. The characteristics of a test method for high-speed signal frequency measurement and signal integrity include the following steps:
Receive the enabling signal sent by the integrated circuit test system, and carry out signal frequency measurement or integrity test according to the type of the enabling signal;
If the signal frequency is measured, the generated square wave is transmitted to the tested digital chip, and the frequency measurement of the output signal of the tested digital chip is carried out after frequency division.
If the signal integrity test is carried out, the generated data signal is transmitted to the tested digital chip, and the output data of the tested digital chip is sampled and stored for comparison.
Whether the digital chip under test is qualified is judged according to the comparison result of the received frequency measurement result and the signal integrity data.

2. As stated in claim 1, the characteristic of the test method for a high-speed signal frequency measurement and signal integrity is that, if the signal frequency is measured, the generated square wave is transmitted to the tested digital chip, and the frequency measurement of the output signal of the tested digital chip is carried out after frequency division, including:
The square wave with a frequency of 100 M generated by the test load plate is transmitted to the tested digital chip according to the received waveform enabling signal. At the same time, the output waveform of the tested digital chip is collected and the output waveform is logically calculated and divided into a 10 M square wave.

3. As stated in claim 2, the characteristic of the test method for a high-speed signal frequency measurement and signal integrity is that if the signal frequency is measured, the generated square wave is transmitted to the tested digital chip, and the frequency measurement of the output signal of the tested digital chip is carried out after frequency division, including:
Adjust the measurement parameters of the time measurement board on the integrated circuit test system, input the frequency-divided output waveform into the adjusted time measurement board for measurement, and output frequency measurement values and comparison results.

4. As stated in claim 1, the characteristic of the test method for high-speed signal frequency measurement and signal integrity is that, if the signal integrity test is carried out, the generated data signal is transmitted to the tested digital chip, at the same time, the output data of the tested digital chip is sampled and stored for comparison, including:
After receiving the signal of the data emitted by the integrated circuit test system, the peripheral circuit is used to send the preset data of the internal register to the tested digital chip, and then the output of the measured digital chip is sampled at a sampling frequency of 200 M, and whether sampling results and preset data are the same is compared in the internal register.

5. As stated in claim 1, the characteristic of the test method for a high-speed signal frequency measurement and signal integrity is that whether the digital chip under test is qualified is judged according to the comparison result of the received frequency measurement result and the signal integrity data, including:
Judge whether the received frequency measurement value is within the allowable fluctuation range during the 100M transmission of the test digital chip:
If the frequency measurement value is greater than or equal to the lower limit of the frequency specification value, and less than or equal to the upper limit of the frequency specification value, the tested digital chip is a good product;
If the measured frequency value is smaller than the lower limit value of the frequency specification value, or greater than the upper limit value of the frequency specification value, the tested digital chip is a defective product.
